(19) United States
(12) Patent Application Publication
(10) Pub. No.: US 2006/0245235 A1
(43) Pub. Date: Nov. 2, 2006

(54) Design and operation of a resistance switching memory cell with diode

(75) Inventors: Juri H. Krieger, Brookline, MA (US); Stuart Spitzer, Lynnfield, MA (US)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: Advanced Micro Devices, Inc.

(21) Appl. No.: 11/119,973

(22) Filed: May 2, 2005

(51) Int. Cl. G11C 11/36

(52) U.S. Cl. 365/115

(57) ABSTRACT

Systems and methodologies are provided for forming a diode component operative (e.g., connected in series) with active and passive layer of a resistance switching memory cell to facilitate programming arrays of memory cells created therefrom. Such a diode component can be part of a memory cell having a passive and active layer. Such an arrangement reduces a number of transistor-type voltage controls and associated power consumption, while enabling individual memory cell programming as part of the array. Moreover, the system provides for an efficient placement of memory cells on a wafer surface, and increases an amount of die space available for circuit design.

### TECHNICAL FIELD

The subject invention relates generally to the design and operation of resistance switching memory cells, and in particular to a memory cell with a diode component.

### BACKGROUND OF THE INVENTION

The proliferation and increased usage of portable computer and electronic devices has greatly increased demand for memory cells. Digital cameras, digital audio players, personal digital assistants, and the like generally seek to employ large capacity memory cells (e.g., flash memory, smart media, compact flash, or the like). Memory cells can be typically employed in various types of storage devices. Storage devices include long term storage mediums such as, for example, hard disk drives, compact disk drives and corresponding media, digital video disk (DVD) drives, and the like. The long term storage mediums typically store larger amounts of information at a lower cost, but are slower than other types of storage devices. Storage devices also include memory devices which are often, but not always, short term storage mediums.

Also, memory cells can generally be subdivided into volatile and non-volatile types. Volatile memory cells usually lose their information if they lose power and typically require periodic refresh cycles to maintain their information. Volatile memory cells include, for example, random access memory (RAM), DRAM, SRAM and the like. Non-volatile memory cells maintain their information whether or not power is maintained to the devices. Examples of non-volatile memory cells include; ROM, programmable read only memory (PROM), erasable programmable read only memory (EPROM), electrically erasable programmable read only memory (EEPROM), flash EEPROM the like. Volatile memory cells generally provide faster operation at a lower cost as compared to non-volatile memory cells. Nonetheless, to retain the information, the stored data typically must be refreshed; that is, each capacitor must be periodically charged or discharged to maintain the capacitor's charged or discharged state. The maximum time allowable between refresh operations depends on the charge storage capabilities of the capacitors that make up the memory cells in the array. The memory device manufacturer typically specifies a refresh time that guarantees data retention in the memory cells. As such, each memory cell in a memory device can be accessed or “read”, “written”, and “erased” with information. The memory cells maintain information in an “off” or an “on” state (e.g., are limited to 2 states), also referred to as “0” and “1”. Typically, a memory device is addressed to retrieve a specified number of byte(s) (e.g., 8 memory cells per byte). For volatile memory devices, the memory cells must be periodically “refreshed” in order to maintain their state. Such memory devices are usually fabricated from semiconductor devices that perform these various functions and are capable of switching and maintaining the two states. The devices are often fabricated with inorganic solid state technology, such as, crystalline silicon devices.

Because of the increasing demand for information storage, memory device developers and manufacturers are constantly attempting to increase speed and storage retrieval for memory devices (e.g., increase write/read speed). At the same time, to reach high storage densities, manufacturers typically focus on scaling down semiconductor device dimensions (e.g., at sub-micron levels). Nonetheless, formation of various transistor type control devices that are typically required for programming memory cell arrays increase costs and reduces efficiency of circuit design.

Therefore, there is a need to overcome the aforementioned deficiencies associated with conventional devices

### SUMMARY OF THE INVENTION

The following presents a simplified summary of the invention in order to provide a basic understanding of one or more aspects of the invention. This summary is not an extensive overview of the invention. It is intended to neither identify key or critical elements of the invention, nor to delineate the scope of the subject invention. Rather, the sole purpose of this summary is to present some concepts of the invention in a simplified form as a prelude to the more detailed description that is presented hereinafter.

The subject invention provides for systems and methods of operating (e.g., programming) memory cells with various layers of alternating passive and active media, which are sandwiched between conducting electrode layers and work in conjunction with a diode element operatively connected (e.g., in series) thereto. Such active and passive layers facilitate migration of charges (e.g., electron and/or positive ions) between electrodes to induce a desired programming state (e.g., a write) in the polymer memory cell, with the diode component facilitating external control (e.g., a voltage control) procedures for programming the memory cell. The diode component can be formed of polymer (e.g., organic material) or other arrangements of semiconducting/conducting materials.

According to one aspect of the subject invention, the diode element(s) that operatively function in conjunction with the memory cell(s), can mitigate power consumption for memory cell arrays, and at the same time further provide for isolation of memory cells from one another, to enable an individual programming of a memory cell as part of the array. Additionally, various stacked arrangements (e.g., three dimensional) of memory cells and diode elements can be fabricated as part of the array arrangement that can include a plurality of rows and columns. This provides for an efficient placement of memory cell(s) on a wafer surface, and increases amount of die space available for circuit design. The diode elements can be chosen such that desired resistivity properties can be achieved, to enable a typically precise adjustment of required threshold properties associated with programming of the memory cell.

In a related aspect, such an arrangement can be programmable via a control component coupled thereto, with the diode elements mitigating (or eliminating) the need for transistor type voltage controls. For example the diode component can reduce a number of transistors required for memory cells by enabling individual memory cells to be programmed independent of other cells. Accordingly, size of the array employing the diode component of the subject invention can be significantly condensed. Like wise, power consumption for such array can be significantly lowered.

To the accomplishment of the foregoing and related ends, the invention, then, comprises the features hereinafter fully described. The following description and the annexed drawings set forth in detail certain illustrative aspects of the invention. However, these aspects are indicative of but a few of the various ways in which the principles of the invention may be employed. Other aspects, advantages and novel features of the invention will become apparent from the following detailed description of the invention when considered in conjunction with the drawings.

To facilitate the reading of the drawings, some of the drawings may not have been drawn to scale from one figure to another or within a given figure.

### BRIEF DESCRIPTION OF THE DRAWINGS

FIG. 1 illustrates a diode element connected to a memory cell according to one aspect of the subject invention.

FIG. 2 illustrates a stacked three dimensional arrangement of diode elements with a memory cell's active and passive layers according to one aspect of the subject invention.

FIG. 3 is a perspective illustration for diode layers operating in a series arrangement with the memory cell.

FIG. 4 is a diagram of a memory array that employs diodes in accordance with an aspect of the subject invention.

FIG. 5 illustrates another diagram of a diode array and control component in accordance with an aspect of the subject invention.

FIG. 6 depicts a diagram of diodic properties exhibited without an applied forward voltage bias in accordance with an aspect of the subject invention.

FIG. 7 illustrates a diagram depicting diodic properties exhibited with an applied forward voltage bias in accordance with an aspect of the subject invention.

FIG. 8 illustrates a diagram depicting diodic properties exhibited with an applied reverse voltage bias in accordance with an aspect of the subject invention.

FIG. 9 illustrates a graph illustrating I-V characteristics for an individual memory cell with a diode component in accordance with an aspect of the subject invention.

FIG. 10 illustrates a schematic control system for programming a memory cell with a diode arrangement, according to one aspect of the subject invention.

FIG. 11 illustrates a schematic system for programming a memory cell according to one aspect of the subject invention.

FIG. 12 illustrates associated voltage-time and current-time graphs for writing a two bit memory cell operation.

FIG. 13 illustrates a flow chart for a methodology according to an exemplary aspect of the subject invention.

### DETAILED DESCRIPTION OF THE INVENTION

The subject invention is now described with reference to the drawings, wherein like reference numerals are used to refer to like elements throughout. In the following description, for purposes of explanation, numerous specific details are set forth in order to provide a thorough understanding of the subject invention. It may be evident, however, that the subject invention may be practiced without these specific details. In other instances, well-known structures and devices are shown in block diagram form in order to facilitate describing the subject invention.

As used herein, the term “inference” refers generally to the process of reasoning about or inferring states of the system, environment, and/or user from a set of observations as captured via events and/or data. Inference can be employed to identify a specific context or action, or can generate a probability distribution over states, for example. The inference can be probabilistic—that is, the computation of a probability distribution over states of interest based on a consideration of data and events. Inference can also refer to techniques employed for composing higher-level events from a set of events and/or data. Such inference results in the construction of new events or actions from a set of observed events and/or stored event data, whether or not the events are correlated in close temporal proximity, and whether the events and data come from one or several event and data sources.

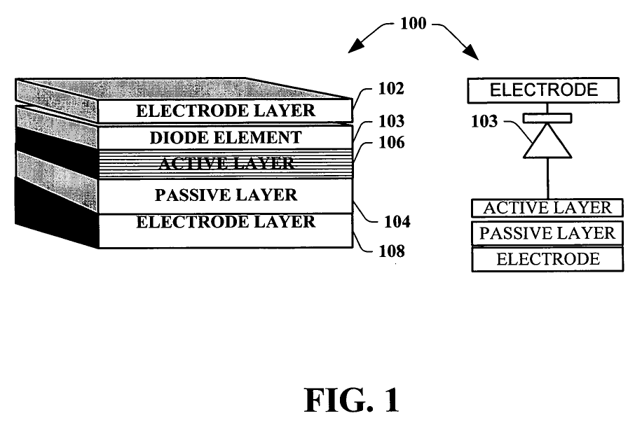

The subject invention provides for systems and methods of operating a memory cell that employs an active layer and a passive layer, and is operatively connected to a diode component. Referring initially to FIG. 1, a diagram of a memory cell 100 having a diode element 103 is illustrated according to one aspect of the subject invention. Typically, memory cell 100 can accept and maintain a plurality of states, in contrast to a conventional memory device that is limited to two states (e.g., off or on). Accordingly, the memory cell 100 can employ varying degrees of conductivity to identify additional states. For example, the memory cell can have a very highly conductive state (very low impedance state), a highly conductive state (low impedance state), a conductive state (medium level impedance state), and a non-conductive state (high impedance state) thereby enabling the storage of multiple bits of information in a single memory cell, such as 2 or more bits of information or 4 or more bits of information (e.g., 4 states providing 2 bits of information, 8 states providing 3 bits of information and the like.)

Switching a memory cell 100 to a particular state is referred to as programming or writing. For example, programming can be accomplished by applying a particular voltage (e.g., 9 volts, 2 volts, 1 volt, and the like) across selected layers of the memory cell, as described in detail infra. Such particular voltage, also referred to as a threshold voltage, can vary according to a respective desired state and is generally substantially greater than voltages employed during normal operation. Thus, there is typically a separate threshold voltage that corresponds to respective desired states (e.g., “off”, “on” . . . ). The threshold value varies depending upon a number of factors including the identity of the materials that constitute the particular memory cell to be programmed, the thickness of the various layers, and the like. It is to be appreciated that FIG. 1 depicts a schematic diagram of a memory cell (and an electrical equivalent) for illustration purposes, and various other configurations are within a realm of the subject invention.

The memory cell 100 with the diode component 103 can further include an electrode layer 108, a passive layer 104 an active layer 106 and a further electrode layer 102. Unlike conventional inorganic memory cells that can maintain only two states, the memory cell 100 is capable of maintaining two or more states, and can hold one or more bits of information. Furthermore, the memory cell 100 is a non-volatile memory cell and consequently, does not require a constant or nearly constant power supply. The electrode 102 can be formed by depositing a first conductive material over control circuitry (not shown) that controls programming of the polymer memory cells, or by directly depositing the first conductive layer over a substrate of silicon wafer. Trenches and/or vias can be formed in the substrate, e.g., as part of the control circuitry, prior to deposition of such conductive material followed by selectively depositing the first conductive material into the trenches. According to one aspect of the subject invention, the electrodes 102, 108 can comprise; tungsten, silver, copper, titanium, chromium, cobalt, tantalum, germanium, gold, aluminum, magnesium, manganese, indium, iron, nickel, palladium, platinum, zinc, alloys thereof, indium-tin oxide, other conductive and semiconducting metal oxides, nitrides and silicides, polysilicon, doped amorphous silicon, and various metal composition alloys. In addition, other doped or undoped conducting or semi-conducting polymers, oligomers or monomers, such as PEDOT/PSS, polyaniline, polythiothene, polypyrrole, their derivatives, and the like can be used for electrodes. In addition, since some metals can have a layer of oxide formed thereupon that can adversely affect the performance of the memory cell, non-metal material such as amorphous carbon can also be employed for electrode formation. Also, other conductive polymers and/or optically transparent oxide or sulfide material can be employed in forming the electrodes 102, and 108. Sandwiched between the two electrodes 102, 108, are a plurality of layers comprising organic, metal organic, and non-organic materials, in the form of an active layer 106, a passive layer 104 and the diode element 103.

The passive layer 104 is operative to transport charge from the electrode 108 to the interface between the active layer 106 and the passive layer 104. Additionally, the passive layer 104 facilitates charge carrier (e.g., electrons or holes) and/or metal ion injection into the active layer 106, and increases the concentration of the charge carrier and/or metal ions in the active layer 106 resulting in a modification of the conductivity of the active layer 106. Furthermore, the passive layer 104 can also store opposite charges in the passive layer 104 in order to balance the total charge of the polymer cell 100. Each of the passive layer 104 and the active layer 106 can comprise further sub layers (not shown.)

The passive layer 104 can contain at least one conductivity facilitating compound that has the ability to donate and accept charges (holes and/or electrons). Generally, the conductivity facilitating compound has at least two relatively stable oxidation-reduction states that can permit the conductivity facilitating compound to donate and accept charges. Passive layer 104 can also be capable of donating and accepting ions. Examples of other conductivity facilitating compounds that can be employed for the passive layer 104 include one or more of the following: tungsten oxide (WO₃), molybdenum oxide (MoO₃), titanium dioxide (TiO₂), copper sulfide (CuₓS), silver sulfide (Ag₂S), copper selenide (CuₓSe), silver selenide (AgₓSe) and the like.

In some instances, the passive layer 104 can act as a catalyst when forming the active layer 106 thereupon. In this connection, a backbone of a conjugated organic molecule can initially form adjacent to the passive layer 104, and grow or assemble away and substantially perpendicular to the passive layer surface. As a result, the backbones of the conjugated organic molecule can be self-aligned in a direction that traverses the two electrodes. The passive layer can be formed by a deposition process (e.g. thermal deposition, PVD, non-selective CVD, and the like) or by a complete sulfidation of pre-deposited thin Cu layer.

Referring now to the active layer 106, such layer can include various organic, metalorganic and non-organic conjugated monomers, olygomers and polymers. Moreover, additional material with donor/acceptor moieties such as; molecules and/or ions with large electric dipole element, polymer ferroelectrics, charge-transfer complexes, organic and inorganic salts, non-organic ferro-electrics, molecules that dissociate in an electric field can also be employed as part of the active layer. As such, examples of organic, non-organic salts, alkalis, acids and molecules that can dissociate in an electric field and/or under light radiation can include the following anions: I, Br, Cl, F, ClO₄, AlCl₄, PF₆, AsF₆, AsF₄, SO₃CF₃, BF₄, BCl₄, NO₃, POF₄, CN, SiF₃, SiF₆, SO₄, CH₃CO₂, C₆H₅CO₂, CH₃C₆H₄SO₃, CF₃SO₃, N(SO₃CF₃)₂, N(CF₃SO₂)(C₄F₉SO₂), N(C₄F₉SO₂)₂, alkylphosphate, organoborate, bis-(4-nitrophenil)sulfonilimide, poly(styrene sulfonate)(polyanions)—and for cations such as: Li, Na, K, Rb, Cs, Ag, Ca, Mg, Zn, Fe, Cu, H, NH₄ and the like. Similarly, examples of clusters employed in the active layer 106 that are based on polymer ferro electrics and non-organic ferro-electrics can include poly(vinylidene fluoride), poly(vinylidene fluoride)/trifluoroethylene, and the like.

According to another aspect of the subject invention, various porous dielectric materials can also be employed as part of the active layer 106 and the passive layer 104. Such porous material for example, can include matter selected from the group of Si, amorphous Si, silicon dioxide (SiO₂), aluminum oxide (Al₂O₃), copper oxide (Cu₂O), titanium dioxide (TiO₂), boron nitride (BN), vanadium oxide (V₂O₃), carbon tri-nitride (CN₃), and ferroelectric materials, including barium-strontium titanate ((Ba, Sr) TiO₃).

Also, the active layer 106 of the memory cell 100 can include polymers with variable electric conductivity. Such polymers with variable electrical conductivity can include; polydiphenylacetylene, poly(t-butyl)diphenylacetylene, poly(trifluoromethyl)diphenylacetylene, polybis-trifluoromethyl)acetylene, polybis(t-butyldiphenyl)acetylene, poly(trimethylsilyl)diphenylacetylene, poly(carbazole)diphenylacetylene, polydiacetylene, polyphenylacetylene, polypyridineacetylene, polymethoxyphenylacetylene, polymethylphenylacetylene, poly(t-butyl)phenylacetylene, polynitro-phenylacetylene, poly(trifluoromethyl)phenylacetylene, poly(trimethylsilyl)pheylacetylene, polydipyrrylmethane, polyindoqiunone, polydihydroxyindole, polytrihydroxyindole, furane-polydihydroxyindole, polyindoqiunone-2-carboxyl, polyindoqiunone monohydrate, polybenzobisthiazole, poly(p-phenylene sulfide) and derivatives with active molecular group.

As used in this application, an active molecule or molecular group can be one that changes a property when subjected to an electrical field or light radiation, (e.g. ionizable group); such as: nitro group, amino group, cyclopentadienyl, dithiolane, metilcyclopentadienyl, fulvalenediyl, indenyl, fluorenyl, cyclobis(paraquart-p-phenylene), bipyridinium, phenothiazine, diazapyrenium, benzonitrile, benzonate, benzamide, carbazole, dibenzothiophene, nitrobenzene, aminobenzenesulfonate, amonobenzanate, ), bipyridyl, bithienyl, thienyl, pyridyl, phenantryl, dialkylbenzyl, and aminobenzoate, and co-polymers of thereof, and molecular units with redox-active metals; metallocenes (Fe, V, Cr, Co, Ni and the like) complex, polypyridine metal complex (Ru, Os and the like)

In another aspect of the subject invention, the active layer 106 can include polymers such as polyaniline, polythiophene, polypyrrole, polysilane, polystyrene, polyfuran, polyindole, polyazulene, polyphenylene, polypyridine, polybipyridine, polyphthalocyanine, polysexithiofene, poly(siliconoxohemiporphyrazine), poly(germaniumoxohemiporphyrazine), poly(ethylenedioxythiophene) and related derivatives with active molecular group. It is to be appreciated that other suitable and related chemical compounds can also be employed including: aromatic hydrocarbons; organic molecules with donor and acceptor properties (N-Ethylcarbazole, tetrathiotetracene, tetrathiofulvalene, tetracyanoquinodimethane, tetracyanoethylene, cloranol, dinitro-n phenyl and so on); metallo-organic complexes (bisdiphenylglyoxime, bisorthophenylenediimine, tetraaza-tetramethylannulene and so on); porphyrin, phthalocyanine, hexadecafluoro phthalocyanine and their derivatives with active molecular group.

In general, the memory cell 100 employing the material discussed supra can exhibit a formation of high conductivity areas, or affect a resistance of the passive and active layers in response to an external stimulus such as an electric voltage, electric current, light radiation, and the like. For example, presence of ferro-electric material can increase internal electric field intensity, and as a result application of a lower external electric voltage can be required for a writing of the memory 100. As explained supra, the active layer 106 can be created on the passive layer 104 and results in an interface between the two layers. Moreover, the active layer 106 can be formed via a number of suitable techniques. One such technique involves growing the active layer 106 in the form of an organic layer from the passive layer 104. Another technique that can be utilized is a spin-on technique, which involves depositing a mixture of the material and a solvent, and then removing the solvent from the substrate/electrode. A further suitable technique is chemical vapor deposition (CVD). CVD includes low-pressure chemical vapor deposition (LPCVD), plasma enhanced chemical vapor deposition (PECVD), and high density chemical vapor deposition (HDCVD). Another technique can be physical vacuum deposition. Additionally, the technique of atomic layer deposition (ALD) can also be employed. It is not typically necessary to functionalize one or more ends of the organic molecule in order to attach it to an electrode/passive layer. A chemical bond can also be formed between the conjugated organic polymer of the active layer 106 and the passive layer 104.

In one aspect of the subject invention, the active layer 106 can also be comprised of a conjugated organic material, such as a small organic molecule and a conjugated polymer. If the organic layer is polymer, a polymer backbone of the conjugated organic polymer can extend lengthwise between the electrodes 108 and 102 (e.g., generally substantially perpendicular to the inner, facing surfaces of the electrodes 108 and 102). The conjugated organic molecule can be linear or branched such that the backbone retains its conjugated nature. Such conjugated molecules have overlapping π orbitals and can assume two or more resonant structures. The conjugated nature of the conjugated organic materials contributes to the controllably conductive properties of the selectively conductive media.

In this connection, the conjugated organic material of the active layer 106 has the ability to donate and accept charges (holes and/or electrons). Generally, the conjugated organic molecule has at least two relatively stable oxidation-reduction states. The two relatively stable states permit the conjugated organic polymer to donate and accept charges and electrically interact with the conductivity facilitating compound.

The organic material employed as part of the active layer 106 according to one aspect of the subject invention can be cyclic or acyclic. For some cases, such as organic polymers, the organic material can self assemble on bottom electrode during formation or deposition. Examples of conjugated organic polymers include one or more of polyacetylene (cis or trans); polyphenylacetylene (cis or trans); polydiphenylacetylene; polyaniline; poly(p-phenylene vinylene); polythiophene; polyporphyrins; porphyrinic macrocycles, thiol derivatized polyporphyrins; poly(p-phenylene)s; poly(imide)s; polymetallocenes such as polyferrocenes, polyphthalocyanines; polyvinylenes; polystiroles; and the like. Additionally, the properties of the organic material can be modified by doping with a suitable dopant.

The electrode 108 is formed on/over the organic material of the active layer 106 and/or the passive layer 104. The electrode 108 can be comprised of similar material as described supra for the electrode 102. Additionally, alloys with phosphorous, nitrogen, carbon, and boron, graphite, conductive oxides and other conductive substances can also be employed.

The thickness of electrode 102 and electrode 108 can vary depending on the implementation and the memory cell being constructed. However, some exemplary thickness ranges include about 0.01 μm or more and about 10 μm or less. The active layer 106 and the passive layer 104 can be collectively referred to as a selectively conductive media or a selectively conductive layer. Conductive properties of such media (e.g., conductive, non-conductive, semi-conductive) can be modified in a controlled manner by applying various voltages across the media via the electrodes 108 and 102.

The organic layer that can form the active layer 106, according to one particular aspect of the subject invention has a suitable thickness that depends upon the chosen implementations of memory cell. Some suitable exemplary ranges of thickness for the organic polymer layer, which in part can form the active layer 106, are about 0.01 μm or more and about 0.2 μm or less. Similarly, the passive layer 104 has a suitable thickness that can vary based on the implementation and/or memory cell being fabricated. Some examples of suitable thicknesses for the passive layer 104 are as follows: a thickness of about 2 Å or more and about 0.1 μm or less. In order to facilitate operation of the memory cell 100, the active layer 106 is generally thicker than the passive layer 104. In one aspect, the thickness of the active layer is from about 0.1 to about 500 times greater than the thickness of the passive layer. It is appreciated that other suitable ratios can be employed in accordance with the subject invention. It is to be appreciated that the various layers employed in fabricating the memory cell can themselves comprise a plurality of sub layers.

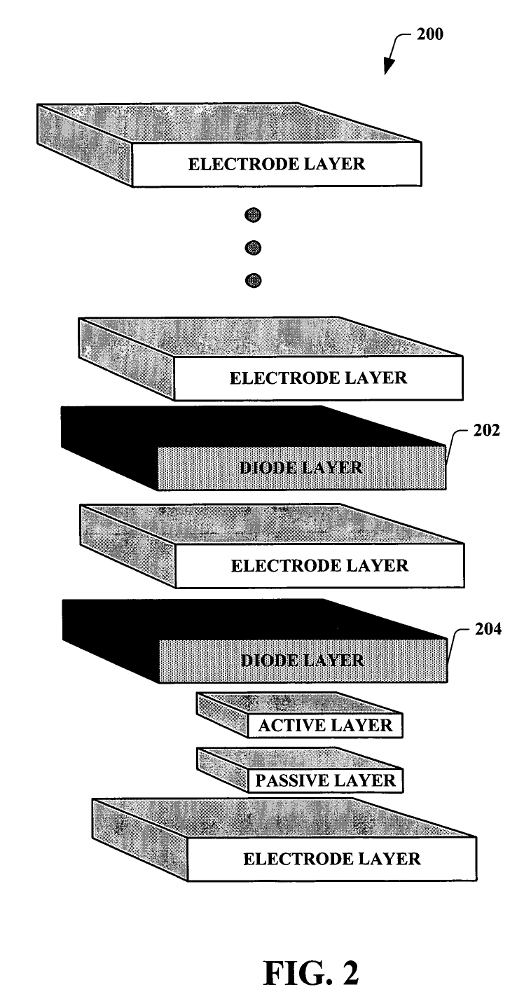

Referring now to FIG. 2, a memory structure 200 according to the subject invention can also be stacked vertically by employing diode layers 202 between memory cells, and/or diode layer 204 as part of an individual memory cell structure. Accordingly, a memory cell stack arrangement can be obtained wherein state changes can occur at desired segments of a memory stack structure. The diode layers 202, 204 can function as an electrical diode to control amount of current flowing through a memory stack or an individual memory cell block, when a voltage is applied thereto. Such layers can for example exhibit characteristics of zener-type diodes, wherein a breakdown voltage level can be inherently predetermined by a composition of the diode. Such breakdown voltage value can be chosen to allow a specific operational function (e.g. write/read/erase) to result in the stacked polymer memory structure.

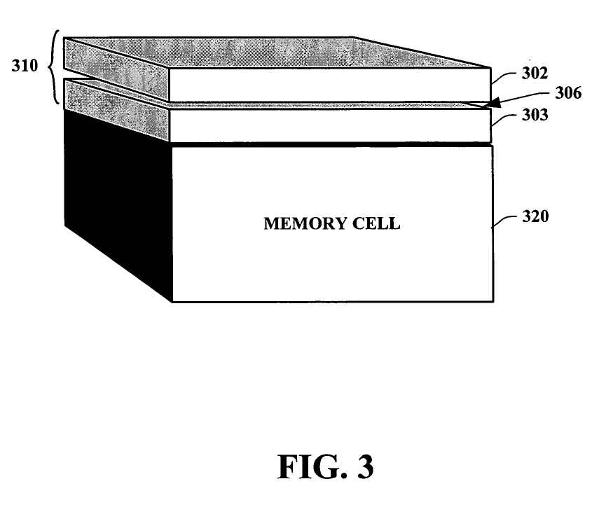

FIG. 3 illustrates a broken perspective of a diode layer 310 coupled to a polymer memory cell 320, which can constitute a building block for a stackable memory device structure according to one aspect of the subject invention. The diode layer 310 comprises a first layer 302 and a second layer 303. A diodic junction 306 can be created between the first and second layers 302, 303 due to a difference in work function between the materials of the two layers and/or due to a charge exchange between the two layers.

The first and second layers 302, 303 can be deposited on a polymer memory cell 320 in any manner that maintains the diodic junction 306. Such can for example include chemical vapor deposition (CVD) processes e.g. atmospheric pressure CVD (APCVD), low pressure CVD (LPCVD), plasma-enhanced CVD (PECVD), photochemical (ultraviolet) (LPCVD), vapor phase epitaxy (VPE), and metalorganic CVD (MOCVD). Additional non-CVD methods such as molecular beam epitaxy (MBE) can also be employed.

The first layer 302 can be comprised of a material that produces a desired diodic junction 306, when working in conjunction with the second layer 303. Accordingly, its composition can be paired appropriately with the second layer 303 composition. The first layer 302 can be a thin or multi-thin film layer. Its composition can be polysilicon, organic and inorganic conductor, crystal state semiconductor, and amorphous state semiconductor material and the like.

The second layer 303 can be comprised of materials necessary to form required diodic junction 306 with the first layer 302. Such desired junction can be a silicon based p-n junction, an organic semiconductor based junction, a metal based organic semiconductor junction, a silicon p- or n-type based organic semiconductor junction and the like. It is to be appreciated that the composition of the second layer 303 can be any number of appropriate materials that when forming a junction with the first layer 302 achieves desired diodic characteristics.

Selecting materials with the appropriate work function differences and/or charge characteristics can alter the diodic effect produced by the two layers 302, 303. Work function is the energy needed to move electrons in the solid from the Fermi level to vacuum level. The work function difference is the characteristics of the contact between the two materials that have differing work functions, defining ohmic or rectifying contact.

In one aspect of the subject invention, the second layer 303 can be comprised of a conductive material such as, aluminum, chromium, copper, germanium, gold, magnesium, manganese, indium, iron, nickel, palladium, platinum, silver, titanium, zinc, tungsten, chrome, alloys thereof, indium-tin oxide, polysilicon, doped amorphous silicon, metal nitrides, carbides, silicides, and the like. Exemplary alloys that can be utilized for the conductive material include Hastelloy®, Kovar®, Invar, Monel®, Inconel®, brass, stainless steel, magnesium-silver alloy, and various other alloys. The thickness of the second layer 303 can vary depending on the implementation and the semiconductor device being constructed. However, some exemplary thickness ranges include about 0.01 μm or more and about 10 μm or less. The diodic layer 310 can control amount of current that flows through the polymer memory cell 320, when a voltage is applied via control circuitry (not shown) across various layers of the polymer memory cell 320, or a group of such memory cells stacked upon each other. Diode characteristics of diodic layer 306 determine how much voltage is required to produce a given amount of current through polymer memory cell 320. It is to be appreciated that there are a wide range of different types of diodes (including Zener-like diodes, Schottky diodes and the like) that provide numerous differing diode characteristics, allowing an almost infinite capability to fine tune the desired regulating effect. Such diodes can function to control the amount of current flowing through a memory stack or an individual memory cell block, when a voltage is applied thereto. In addition, such diodes can for example exhibit Zener-type characteristics, wherein a breakdown voltage level can be inherently predetermined by a composition of the diode. Such breakdown voltage value can be chosen to allow a specific operational function (e.g. write/read/erase) to result in the cell.

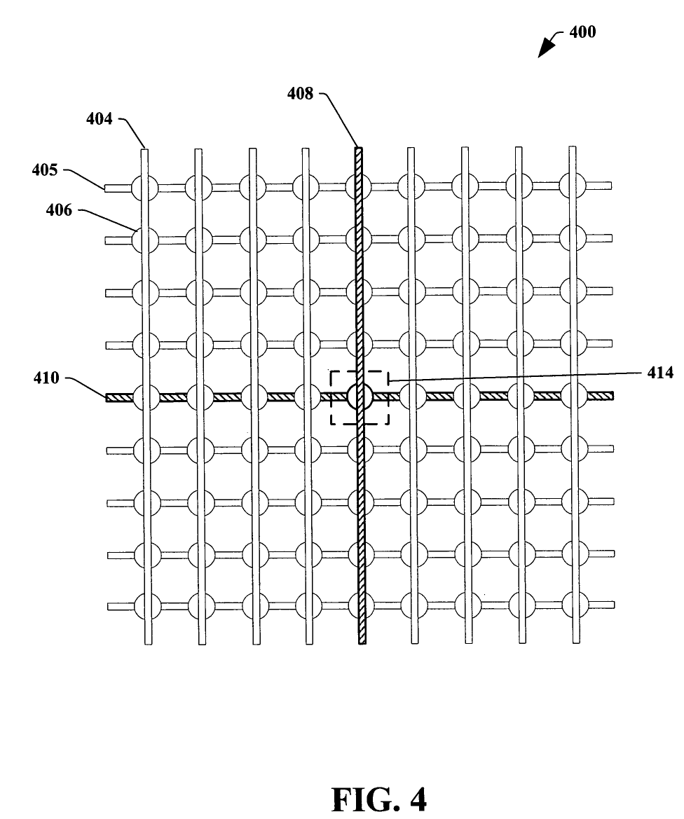

Turning now to FIG. 4, a top view of a semiconductor device array 400 that employs diode elements in accordance with an aspect of the subject invention is depicted. Such an array is generally formed on a silicon based wafer, and includes a plurality of columns 404, referred to as bitlines, and a plurality of rows 405, referred to as wordlines. Such bit line and wordlines can be connected to the top and bottom metal layers of memory components. The intersection of a bitline and a wordline constitutes the address of a particular memory cell. Data can be stored in the memory cells (e.g., as a 0 or a 1) by choosing and sending signals to appropriate columns and rows in the array (e.g., via a column address strobe CAS 406 and a row address strobe RAS 408, respectively.) The diode element of the subject invention mitigates requirements of employing transistors-capacitor pairs when programming memory cells in such array. For example, when a memory cell 414 has been chosen to be programmed, the appropriate bitline 408 and wordline 410 that intersect the memory cell 414 are energized to an appropriate voltage level necessary for the desired function (e.g. read, write, erase). Even though other memory cells exist along bitline 408 and wordline 410, only the cell 414 at the intersection of the appropriate bitline 408 and wordline 410 actually changes to the appropriate state. For example, it can be the combination of the two voltage level changes that alters the memory cell 414 state. The bitline voltage level alone and the wordline voltage level alone are not enough to program the other devices connected to these lines. Accordingly, only the device 414 that is connected to both lines can surpass the threshold voltage levels set by the diode element integral to a memory cell of the subject invention. Thus, diode elements of other bitlines and wordlines can be tuned such that memory cells are typically undisturbed during the processes. Such positioning of the diode element with the memory cell mitigates a number of transistor-type voltage controls as part of programming memory cells of an array. Accordingly, a diode built in association (e.g., in series) with a memory element can be fabricated enabling an efficient placement of memory cells on a wafer surface, while increasing an amount of die space available for circuit design.

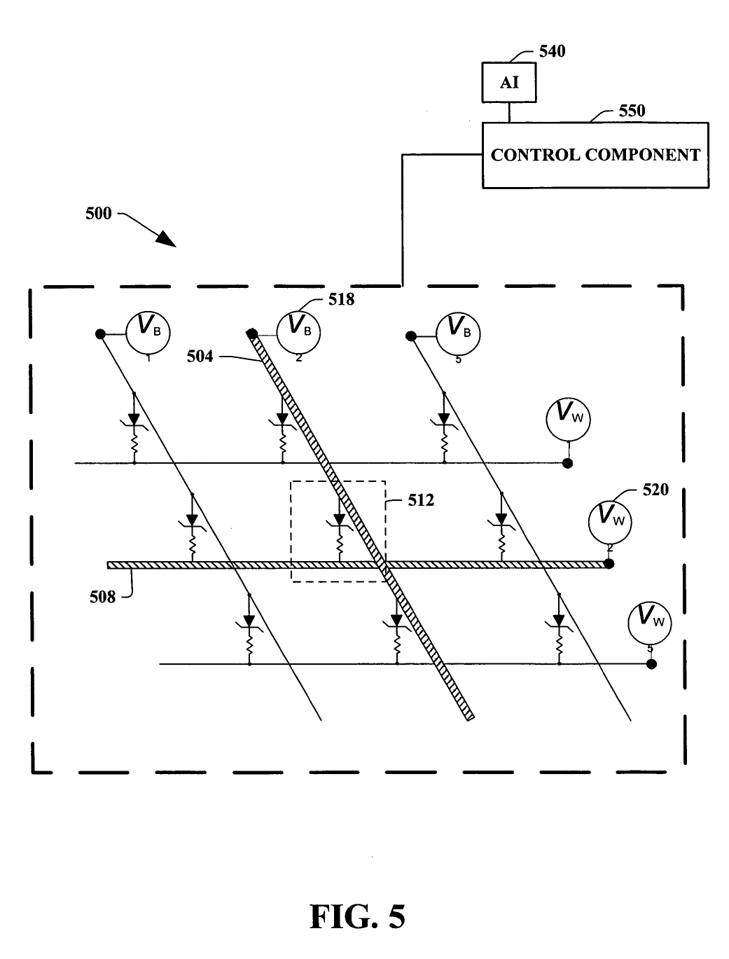

FIG. 5 illustrates another schematic diagram of a memory array in accordance with an aspect of the subject invention. Array 500 is depicted with diode components, specially tuned, that can operate in conjunction with memory cells to be programmed (e.g., diode 512 connected in series with its memory cell). A plurality of voltage sources (e.g., 518, 520) can operate on various bitlines (e.g., 504) and wordlines (e.g., 508) for changing a state of designated memory cells. A control component 550 can regulate such voltage sources, and program desired memory cells to a designated value, (e.g., program memory cell with diode connected in series thereto 512), while mitigating employment of transistor type elements. The control component can further include an artificial intelligence component 540 for programming of memory cells. For example, the programming can be facilitated via an automatic classification system and process. Such classification can employ a probabilistic and/or statistical-based analysis (e.g., factoring into the analysis utilities and costs) to prognose or infer an action that is desired to be automatically performed. For example, a support vector machine (SVM) classifier can be employed. A classifier is typically a function that maps an input attribute vector, x=(x1, x2, x5, x4, xn), to a confidence that the input belongs to a class—that is, f(x)=confidence(class). Other classification approaches include Bayesian networks, decision trees, and probabilistic classification models providing different patterns of independence can be employed. Classification as used herein also is inclusive of statistical regression that is utilized to develop models of priority.

It is to be appreciated that the subject invention can employ classifiers that are explicitly trained (e.g., via a generic training data) as well as implicitly trained (e.g., via observing system behavior, receiving extrinsic information) so that the classifier(s) is used to automatically determine according to a predetermined criteria which regions to choose. For example, with respect to SVM's—it is to be appreciated that other classifier models may also be utilized such as Naive Bayes, Bayes Net, decision tree and other learning models—SVM's are configured via a learning or training phase within a classifier constructor and feature selection module.

The following discussion relates to typical operation of a diode element that can provide a helpful discussion to understanding various aspects of the subject invention. Typically, a diode is a two-region device separated by a junction. It either allows current to pass or prohibits it. Whether the current is allowed to pass, is determined by the voltage level and polarity, referred to as biasing. Generally, when the polarity of the applied voltage matches the polarity of the diode region at the junction, the diode is considered to be forward biased, permitting the current to flow. When the polarities are opposing, the diode is considered to be reverse biased, inhibiting the current flow. Current flow in a reverse biased diode can be achieved by raising the applied voltage to a level that forces the junction into breakdown. The current flow can once again stop when the applied voltage level is reduced below the level required to cause breakdown.

In general, the relationship between the current and voltage can be expressed using the ideal diode equation:

$${I}_{D} = {I}_{S} ( {ⅇ}^{\frac{{qV}_{D}}{nkT}} - 1 )$$

where I_{D} is the current through the diode and V_{D} is the voltage across the diode. Additionally, I_{S} is the reverse saturation current (the current that flows through the diode when it is reverse biased—V_{D} is negative), q is the electronic charge (1.602×10⁻¹⁹ C), k is Boltzmann's constant (1.38×10⁻²³ J/° K), T=junction temperature in Kelvins, and n is the emission coefficient.

Although a reverse biased diode is ideally non conducting, a small current still flows through the semiconductor junction when the voltage is applied due to the presence of minority carriers. The total reverse current can be approximated by:

$$Js = q \sqrt{\frac{{D}_{p}}{{τ}_{p}}} \frac{{n}_{i}^{2}}{{N}_{D}} + \frac{{qn}_{i} W}{{τ}_{n}}$$

where Dₚ is the hole diffusion coefficient, τₚ and τₙ are the effective lifetime constants of the holes and the electrons in a depletion region. The reverse current is the sum of the diffusion component in the neutral region and the generation current in the depletion region. The diffusion current is due to the change in concentration of the charges through the material. The second term comes from the emission of charges through the deep levels present within an energy band gap. Additionally, W is the width of the depletion region, nᵢ is the intrinsic density and N_{D} is the donor density.

The work functions of the two materials used to form a diodic junction determine the potential barrier formed at the junction. The work function is defined as the energy difference between the vacuum level and the Fermi level, E_{F}. As an example, assume a metal layer and an n-type semiconductor layer are used to form the diodic layer of the subject invention. Therefore, the work function of the metal layer is denoted by qφₘ and the semiconductor layer is denoted q(χ+Vₙ), where χ, the electron affinity of the semiconductor, is the difference in energy between the bottom of the conduction band, E_{C}, and the vacuum level. Additionally, qVₙ is the difference between E_{C} and the Fermi level.

For example, when a metal and a semiconductor layer come in contact, a charge can flow from the semiconductor to the metal. Typically, the semiconductor can be n-type, so its work function is smaller than the metal work function. As the distance between the two layers decreases, an increasing negative charge is built up at the metal surface. At the same time, an equal and opposite charge exists in the semiconductor. When the distance between the layers is comparable with the interatomic distance, the gap becomes transparent to electrons. The limiting value for the barrier height qφ_{Bn} is given by:
qφ_{Bn}=q(φₘ−χ).
The barrier height is then the difference between the metal work function and the electron affinity of the semiconductor. It is to be appreciated that the formulas discussed supra provide a basic understanding for various attributes of a diodic layer. One skilled in the art can appreciate that the above discussion provides a basic understanding of diodic properties.

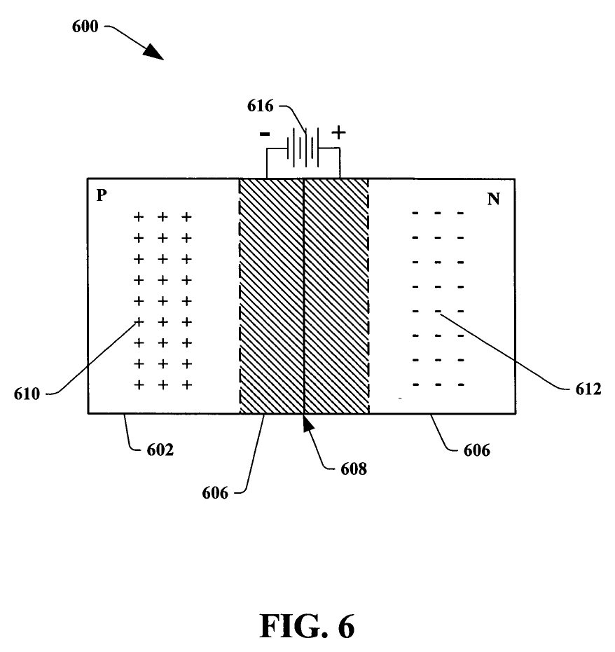

Turning to FIG. 6, a diagram depicting diodic properties exhibited without an applied voltage bias 600 in accordance with an aspect of the subject invention is shown. A p-type material 602 and an n-type material 606 are joined to form a diodic junction 608. The p-type material 602 contains a majority of positive carriers 610, while the n-type material contains a majority of negative carriers 612. When the two materials are joined, the negative and positive carriers exchange holes and electrons in a diffusing process known as junction recombination. This recombination reduces the number of free electrons and holes in the junction region, creating a depletion region 606. On the p-side 602 of the junction 608 in the depletion region 606, a layer of negatively charged ions exists. The n-side 606 of the depletion region 606 contains a layer of positively charged ions. This produces an electrostatic field 616 across the depletion region 606. The diffusion of electrons and holes continues until equilibrium is reached, dictated by the amount of energy required to overcome the electrostatic field 616. For carriers to move across the junction 608 beyond equilibrium, they must have enough potential to overcome the barrier presented by the electrostatic field 616.

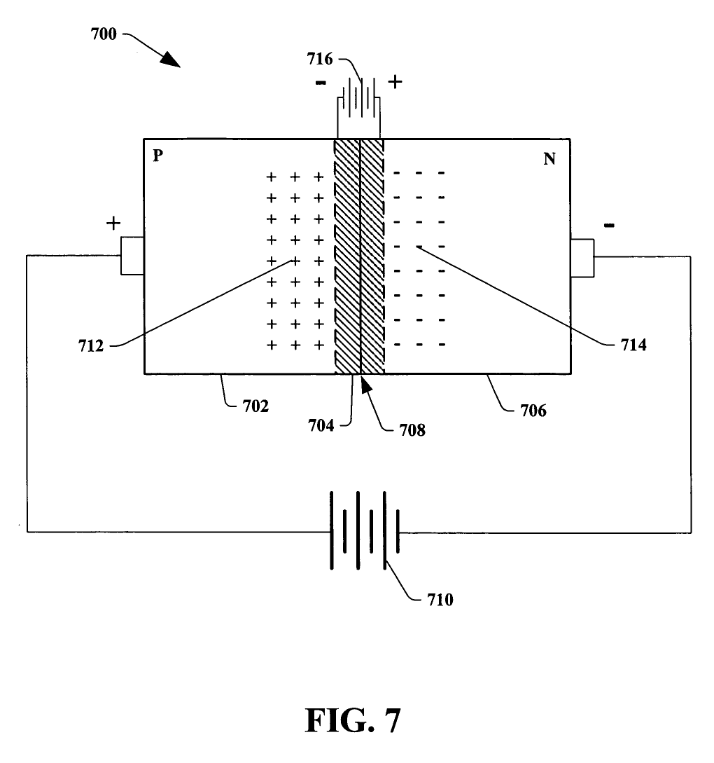

FIG. 7 depicts a diagram of diodic properties exhibited with an applied forward voltage bias 700 in accordance with an aspect of the subject invention. To forward bias a diodic junction 708, an external voltage 710 is applied with a polarity that opposes an electrostatic field 716 in a depletion region 704. This causes the depletion region 704 to be reduced, allowing the diodic junction 708 to present minimal resistance to the flow of current. Applying the external voltage 710 in this polarity forces positive carriers 712 in a p-type material 702 to be repelled by the positive potential of the external voltage 710 connected to the p-type material 702. Some of the repelled carriers combine with negative ions in a depletion region 704. Similarly, the negative potential of the external voltage 710 connected to an n-type material 706 drives negative carriers 714 towards the diodic junction 708. Some of these carriers combine with positive ions in the depletion region 704. This aids in reducing the width of the depletion region 704, reducing an electrostatic field 716 generated in the depletion region 704.

Current flow in a forward biased p-n junction is by the majority carriers 712, 714. Increasing the external voltage 710 also increases the number of majority carriers 712, 714 arriving at the diodic junction 708, elevating the current flow.

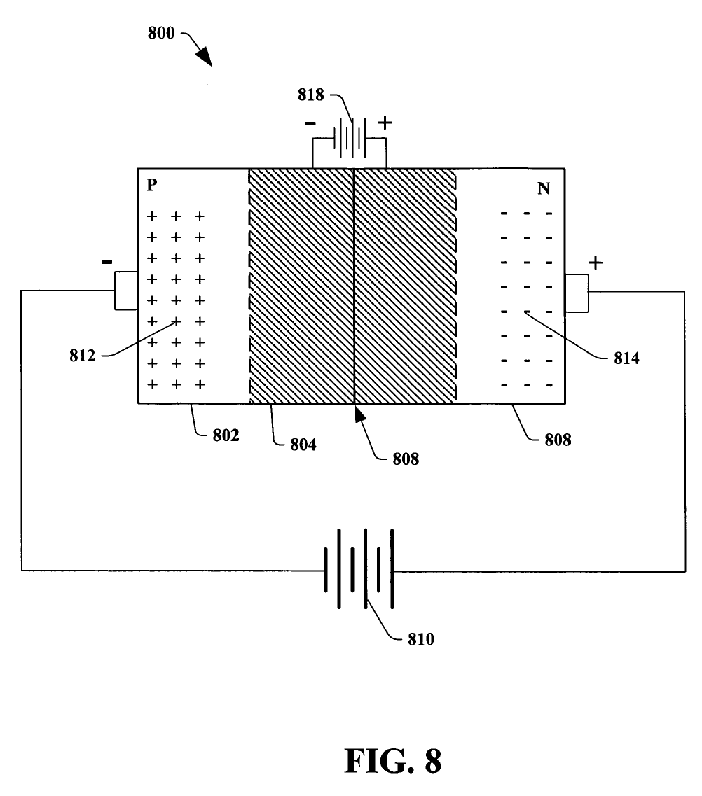

Now referring to FIG. 8, a diagram depicting diodic properties is illustrated with an applied reverse voltage bias 800 in accordance with an aspect of the subject invention is shown. To reverse bias a diodic junction 808, an external voltage 810 is applied with a polarity that enhances an electrostatic field 818 generated by a depletion region 804. This causes the depletion region 804 to enlarge, allowing the diodic junction 808 to present maximum resistance to the flow of current. Applying the external voltage 810 in this polarity allows positive carriers 812 in a p-type material 802 to be attracted by the negative potential of the external voltage 810 connected to the p-type material 802. Similarly, the positive potential of the external voltage 810 connected to an n-type material 808 attracts negative carriers 814 away from the diodic junction 808. This aids in enlarging the width of the depletion region 804, increasing the electrostatic field 818. More negative ions are now on the p-side 802 and more positive ions are now on the n-side 808. This increased number of ions prohibits current flow across the diodic junction 808 by the majority carriers 812, 814. However, current flow is not absolutely zero due to current flow by minority carriers which still cross the diodic junction 808. Generally, this current is considered negligible compared to the current flow of majority carriers.

Current flow in a reverse biased p-n junction is by minority carriers. In some types of diodes, the reverse bias voltage 810 can be raised to a predetermined level which produces a breakdown of the diodic junction 808. At this voltage level, current will flow through the device. Once the voltage level is reduced less than the breakdown voltage level, the diodic junction 808 will once again prohibit current flow.

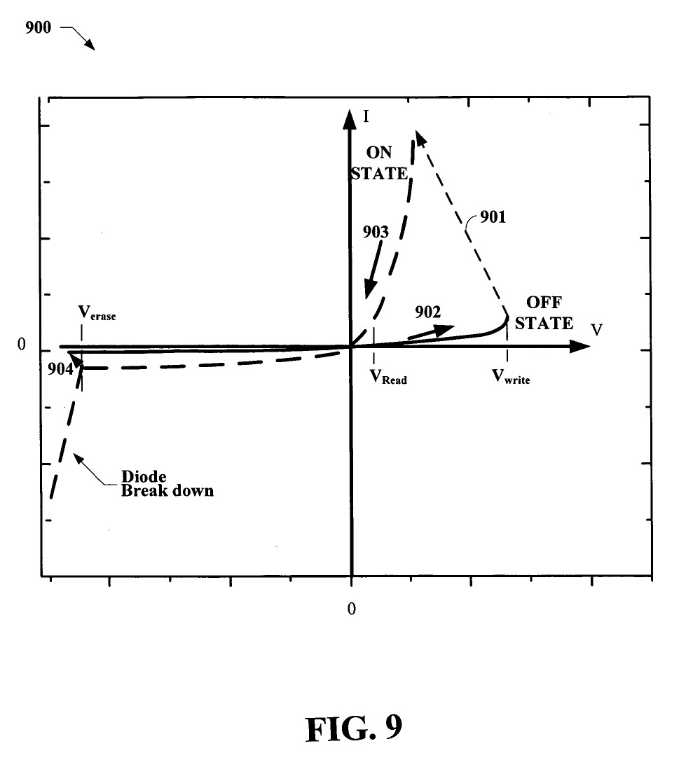

FIG. 9 illustrates an exemplary current-voltage graph 900 for a memory cell working in conjunction with a diode operatively connected thereto, during “On” and “Off” states. As illustrated, an arbitrary current requires a higher voltage for an “Off” state of the memory cell, when compared to an “On” state. The “On” and “Off” states can be distinguished by choosing a current and measuring a respective voltage and vice versa. Accordingly, employing the diode according to the subject invention facilitates blocking of current in the negative voltage direction—absent a diode working in conjunction with the memory cell, the memory cell can exhibit an I-V graph that is typically symmetrical (not shown) with respect to the point of origin Such blocking of power in a stand by or neutral state of a memory device reduces power consumption and can further enable a programming of desired memory cell as part of an array, as explained supra.

As illustrated, slope of line 901 typically reflects the current limiting resistance of the circuit (e.g., reflecting a load line that can be varied by a combination of the applied voltage and a resistance in series with the memory component.) Such line depicts a typically transitional state when switching the device.

If the voltage is increased in a direction of the arrow 902 by tracing the “OFF” state (solid curve) such that the a write voltage threshold (V_{write}) is obtained, the memory cell with its diode component then switches from an “OFF” state of low resistance to an “ON” state of high resistance. Subsequently, a decrease of voltage traces in a direction of arrow 903 into negative voltage values following a path of the ON state (dashed curve) representing diode characteristics, and reverse leakage current. Thereafter, an erase voltage threshold point (Vₑᵣₐₛₑ) can be obtained that can then switch the device from an “ON” state to an “OFF” state as depicted by arrow 904. Nonetheless, if before reaching such erase threshold voltage the voltage is reversed the I-V trace will retrace back on the “ON” state curve in a direction opposite the arrow 903. A read threshold voltage can be positioned any place in between Vₑᵣₐₛₑ and V_{write,} and can be typically positioned such that a low power consumption be required for a read operation. Generally, the write voltage can be between 1 to 10 volts, and the erase voltage between −0.9 to −9 volts depending upon fabrication of the polymer memory cell and programming methodologies. It is to be appreciated that depending upon the load resistance and manner of limiting the current, a family of curves (not shown) can be obtained that pass through predetermined points on line 901, to define other ON states with different resistances, and hence providing for a multi bit operation of the device. Accordingly, a plurality of ON states can be defined for a memory cell.

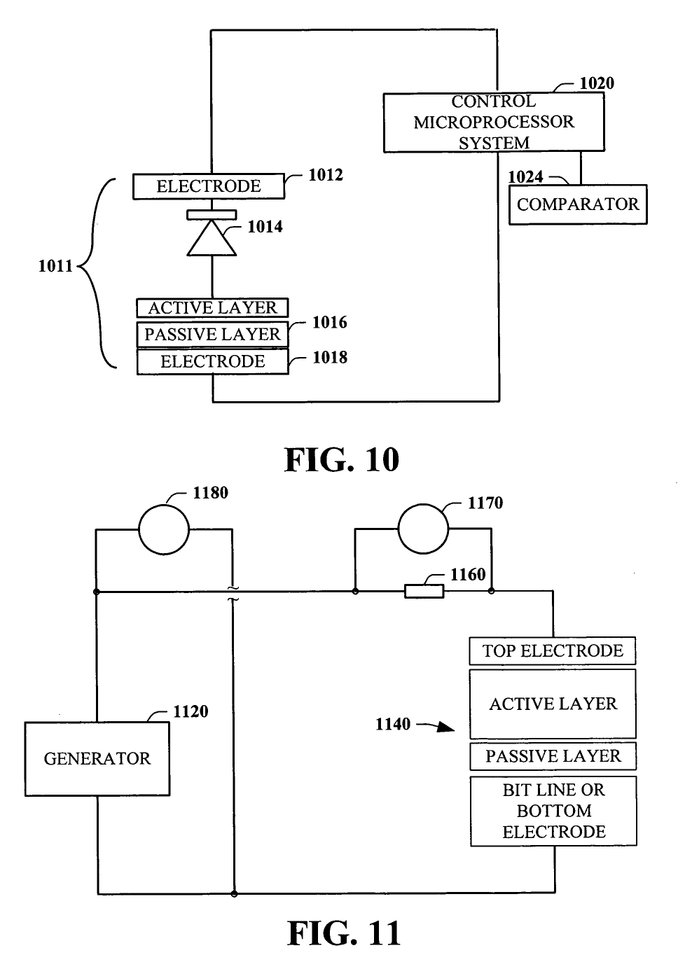

FIG. 10 illustrates a schematic programming system for a memory cell 1011, as part of an array (not shown), and a diode 1014 connected thereto, with a control microprocessor system 1020. The control system 1020 can be part of a suitably programmed general purpose computer of a network and can also be implemented by employing a plurality of separated dedicated programmable integrated or other logic devices. Other information display devices (e.g. monitors, displays and the like), as well as user input devices can be operatively connected to the input/output of such processor. The controller 1020 can actively trace and control a program state of the memory cell 1011. For example, the microprocessor system 1024 can provide a programming signal, e.g., a voltage applied to the memory element 1011, and detect an ensuing electric current that flows through it. When such current is detected to be at a predetermined value that represents a particular resistance of the memory element 1011, the voltage can be removed, and programming stopped. Such can be accomplished by comparing the current via a comparator 1024 to reference values. Accordingly, the memory cell 1011 can be programmed to a predetermined state. Typically for such a memory cell, upper and lower electrodes (1012, 1018) sandwich various other active, and passive layers, which can also include various light emitting material, such as; light emitting structure, photo resistance, or photo sensors. The electrodes (e.g., 1012, 1018) can be comprised of a conductive material such as, aluminum, chromium, copper, germanium, gold, magnesium, manganese, indium, iron, nickel, palladium, platinum, silver, titanium, zinc, alloys thereof, indium-tin oxide, polysilicon, doped amorphous silicon, metal silicides, and the like. Exemplary alloys that can be utilized for the conductive material include Hastelloy®, Kovar®, Invar, Monel®, Inconel®, brass, stainless steel, magnesium-silver alloy, and various other alloys.

The thickness of the electrodes can vary depending on the implementation and the memory device being constructed. However, some exemplary thickness ranges include about 0.01 μm or more and about 10 μm or less. The electrodes can be placed in an alternating fashion among various layers of for example semiconductor layers, polymer layers, and passive layers.

Referring now to FIG. 11 a circuit that programs a memory cell having passive and active layers according to one aspect of the subject invention is illustrated. The control system for such circuit includes a generator 1120 that can provide a controllable electrical current level (e.g., a programmable current) during information writing and/or recording of the memory cell 1140. The memory cell 1140 includes two electrodes that sandwich various layers, e.g., a selective conductive layer (functional layer) comprising an active layer (e.g., organic layer) and a passive layer, as explained in detail supra. It is to be appreciated that the subject invention is not so limited and other layers such as functioning zone layers; barrier layers; active/passive layers, and the like can also be employed with other aspects of the subject invention.

A ballast resistor 1160 is operatively connected to the memory cell 1140, and has a resistance that increases rapidly with increases in current through the resistor 1160, thereby tending to maintain an essentially constant current despite any variations in the line voltages. Registering devices 1170 and 1180 can monitor circuit conditions during various programming stages of the memory cell 1140. For example, the value of the current flowing through the memory cell can be obtained by measuring voltage on the ballast resistor 1160, and such registering device can include voltmeters, oscillographs, recorders and other devices employed for monitoring circuit conditions at any moment.

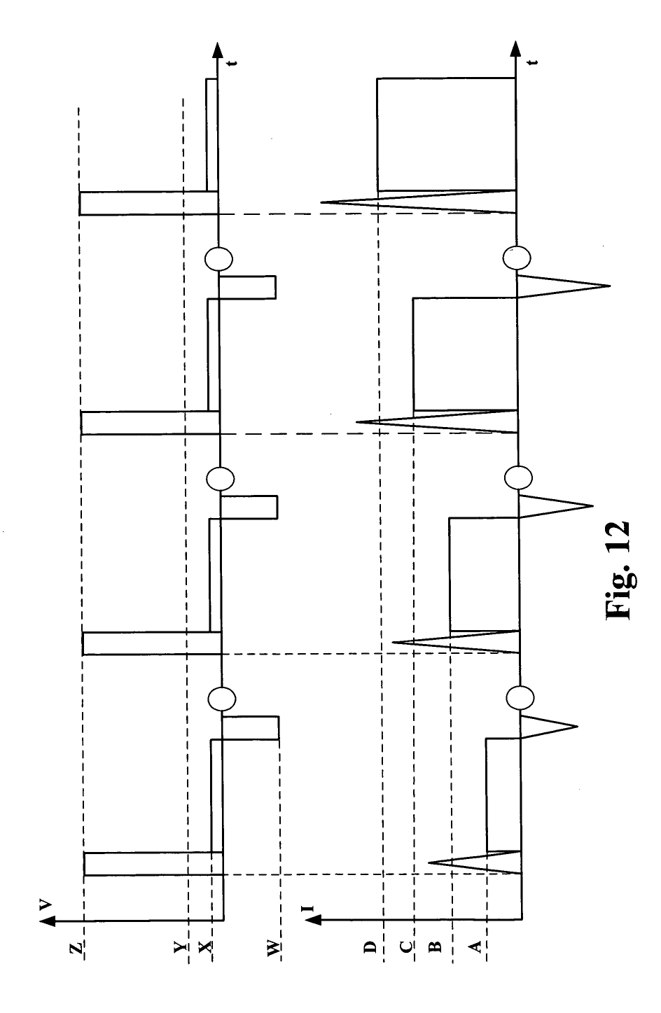

According to one particular methodology of the subject invention, the generator 1120 forms an initial voltage pulse that exceeds a threshold value required for programming a memory cell. For example, FIG. 12 illustrates associated voltage-time and current-time graphs of such a methodology for writing a two bit memory cell operation. Voltage levels “Z” and “Y” depict an initial voltage pulse and a threshold voltage respectively. The values of the current flowing through the memory cell 1140 can then be obtained by measuring voltage on the ballast resistor 1160. As such, current flowing through the memory cell can be controlled such that the various electric current pulse states correspond to respective bits of information, written in to the memory cell. For example and as depicted in FIG. 12; electric current level “A” can designate a value “00”, electric current level “B” can designate a value “01”, electric current level “C” can designate a value “10”, and electric current level “D” can designate the value “11”, all which are programmable into the memory cell 1140. Next, and after the electric current pulse reaches the desired programmed state, the write programming is complete, and the programming voltage switched off. Similarly, to read bits of information from the memory cell 1140, a reading voltage “X” that is lower than the threshold voltage value “Y” is generated via the generator 1120. Based on the amount of current flowing through the ballast resistor 1160 of FIG. 11, the resistance of the memory cell 1140 can then be estimated, and an electric current flowing through it obtained. Such electric current can then correspond to a reference electric current, to verify a programmed state of the memory cell. Likewise, to erase information, the generator 1120 creates a negative voltage pulse W, which can create a current, controlled to reach an erase threshold value flowing through the memory cell. It is to be appreciated that other properties besides voltage, current, or impedance can be employed to program a memory cell having a functioning zone.

For example, the controlled value can be an intensity of light (optical programming when light sensor/emitter layers are employed), or amount of time that the memory cell is subject to an external stimulus and/or signal. Such can also depend upon the structure of a particular memory cell, and material employed in its fabrication, as for the particular memory structure illustrated by FIG. 11, it may be necessary to return the cell to its initial state and erase recorded information before a further write operation can be performed.

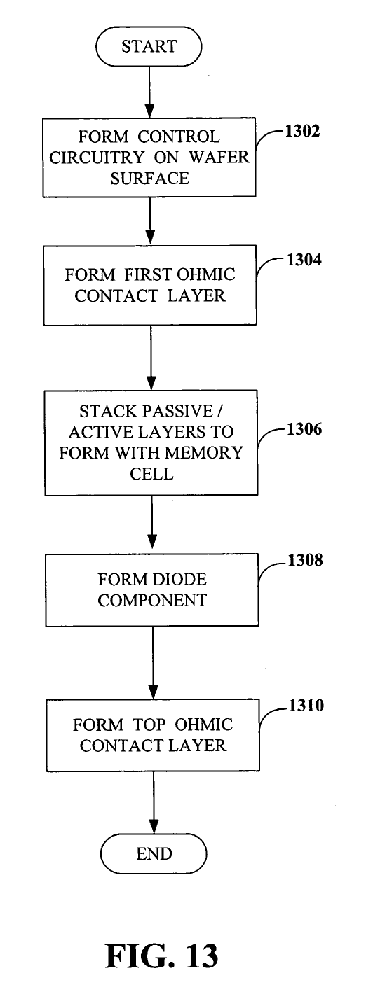

FIG. 13 illustrates a methodology according to one aspect of the subject invention. While the exemplary method is illustrated and described herein as a series of blocks representative of various events and/or acts, the subject invention is not limited by the illustrated ordering of such blocks. For instance, some acts or events may occur in different orders and/or concurrently with other acts or events, apart from the ordering illustrated herein, in accordance with the invention. In addition, not all illustrated blocks, events or acts, can be required to implement a methodology in accordance with the subject invention. Moreover, it will be appreciated that the exemplary method and other methods according to the invention can be implemented in association with a deposition and etch process for IC fabrication, and/or a damascene fill and polish procedure as well as in association with other systems and apparatus not illustrated or described.

Initially, at 1302 a control component circuitry, as described in detail supra can be deposited on a wafer surface. Such control component can facilitate a programming of various memory cells employed as part of an array of memory cell of the subject invention. Next, and at 1304 a bottom ohmic contact layer is being deposited, e.g., as part of an interconnect line as described in detail supra, which can act as a lower electrode for memory cells as part of the array. Next at 1306 various layers of: passive media, active media, are deposited to form a memory cell. At 1308, and over such stacked layer, a diode component can be positioned. Next over the diode component an electrode layer can be positioned at 1310 e.g., as part of an interconnect line to connect such memory cell with other parts of a memory cell array circuit.

In one particular aspect, the diode component formed at 1308 can comprise one or more layers of at least one p-type organic material, and the top electrode which contacts such component, can comprise a material having a high work function for electrons equal to or greater than about 4.2 eV. Moreover, the electrode can include at least one electrically conductive material selected from the group consisting of Au, W, Ti, Pt, Ag, Mo, Ta, Cu, metal oxides (e.g., indium-tin oxide, ITO), and organic polymers, as described in detail supra. In a further aspect of the methodology of the subject invention, the diode can include one or more layers of at least one n-type organic material, and the contacting top electrode can include a material having a low work function for electrons less than about 4.2 eV. The top electrode can further include at least one electrically conductive material selected from the group consisting of Ca, Mg, Mg combined with another metal, Al, Al alloys, Li—Al alloys, and metal-dielectric combinations. Also the diode component can further comprise a combination of metal and organic material, e.g., a p-type layer including copper phthalocyanine (CuPc) and an n-type layer including copper hexadecaflouoro phthalocyanine (F16 CuPc).

In a related aspect, the diode component can also include a polymeric metallic phthalocyanine (MPc) or a metal hexadecaflouoro phthalocyanine (F16 MPc), wherein the metal (M) may include Cu, Co, Ni, Fe, or Ti. According to a further aspect of the subject invention, the diode can include one or more layers of at least one aromatic amine, with the top electrode including at least one electrically conductive material having a high work function for electrons greater than about 4.2 eV. Additionally, the diode component can include a layer of at least one aromatic amine and a layer of a different type organic material, or a pair of layers each comprising at least one aromatic amine. The thickness of the diode component can range from about 10 Å to 1 mm, between about 10 Å and 1 μm, and between about 10 Å and 1,500 Å.

The following examples illustrate various particular aspects of the subject invention. Unless otherwise indicated in the following examples and elsewhere in the specification and claims, all parts and percentages are by weight, all temperatures are in degrees Centigrade, and pressure is at or near atmospheric pressure.

### EXAMPLE 1

Ti/LiₓVSe₂/Al (or Ti), wherein LiₓVSe₂ serves as a combined active and passive layer, with x accepting suitable values to create a stable compound. The first, or lower electrode of Ti or Al can be vapor deposited, as explained in detail supra on the surface of an insulating layer at a thickness of about 3,000-8,000 Å. The LiₓVSe₂ combined active and passive layer can be deposited via a CVD process at a thickness of about 50-300 Å, with Li ions intercalated by treatment with a solution of n-butyl lithium in hexane. The second, or upper electrode of Ti or Al can be vapor deposited on the LiₓVSe₂ layer at a thickness of about 3,000-8,000 Å.

### EXAMPLE 2

Ti/LiₓTiS₂/VSe₂/Al (or Ti), wherein LiₓTiS₂ serves as a passive layer and VSe₂ serves as an active layer, with x accepting suitable values to create a stable compound. Such cell can be fabricated in similar manner as Example 1, except that the VSe₂ active layer can be deposited by a CVD process on the surface of the LiₓTiS₂ passive layer prior to deposition of the second, upper electrode. The thickness of the VSe₂ active layer can be about 50-300 Å.

### EXAMPLE 3

Ti/LiₓVSe₂/HfSe₂/Al (or Ti), wherein LiₓVSe₂ with x accepting suitable values to create a stable compound that serves as a passive layer. and HfSe₂ serves as an active layer, each layer being deposited via a CVD process.

### EXAMPLE 4

Ti/LiₓVSe₂/Li₃N₃/HfSe₂/Al (or Ti), wherein LiₓVSe₂ serves as a passive layer, Li₃N serves as a barrier layer, and VSe₂ serves as an active layer. The Li₃N barrier layer can also be deposited via CVD and is about 20-100 Å thick.

### EXAMPLE 5

Ti/LiₓTiS₂/a-Si/Al (or Ti), structure similar to Example 2, except for an amorphous silicon (a-Si) active layer (formed by CVD) substituted for the VSe₂.

### EXAMPLE 6

Ti/LiₓTiS₂/p-Si/Al (or Ti), similar to Example 5, except for a porous silicon (p-Si) active layer (formed by CVD) substituted for a-Si.

### EXAMPLE 7

Ti/LiₓTiS₂/p-SiO₂/Al (or Ti), similar to Examples 5 and 6, except for a porous silicon dioxide (p-SiO₂) active layer (formed by CVD or from a sol-gel of tetraethoxyorthosilicate, TEOS) substituted for a-Si or p-Si.

### EXAMPLE 8

Ti/Cu₂₋ₓS/p-SiO₂/Al (or Ti), similar to Example 7, except that Cu₂₋ₓS (x accepting a suitable value for example between 1 and 2) is substituted for LiₓTiS₂ as a passive layer. The Cu₂₋ₓS passive layer can be formed by first depositing (e.g., vapor depositing) an about 100-300 Å thick layer of Cu on the surface of the lower electrode (Ti), followed by an about 15 min. treatment of the Cu layer with H₂S gas in a chamber at room temperature for reaction to form Cu₂₋ₓS.

### EXAMPLE 9

Ti/Cu₂₋ₓS/Cu₂O/Al (or Ti), similar to Example 8, except that CuO is substituted for p-SiO₂ as an active layer. The Cu₂₋ₓS passive layer can be first formed by depositing (e.g., vapor depositing) an about 200-400 Å thick layer of Cu (250 Å presently preferred) on the surface of the lower electrode (Ti), followed by an about 10 min. treatment of the Cu layer with H₂S gas in a chamber at room temperature for reaction to form Cu₂₋ₓS. The Cu₂₋ₓS layer is then reacted with O₂ gas in a chamber for about 10 min. to form a layer of Cu₂O over the layer of Cu₂₋ₓS.

### EXAMPLE 10

Ti/Cu₂₋ₓSe/p-SiO₂/Al (or Ti), similar to Example 8, except that Cu₂₋ₓSe is substituted for Cu₂₋ₓS as the passive layer by using H₂Se gas in place of H₂S for reaction with the initially deposited Cu layer.

### EXAMPLE 11

Ti/Ag₂S/p-SiO₂/Al (or Ti), similar to Example 8, except that Ag₂S is substituted for Cu₂₋ₓS as the passive layer. The Ag₂S passive layer can be formed by first depositing (e.g., vapor depositing) an about 100-300 Å thick layer of Ag (150 Å presently preferred) on the surface of the lower electrode (Ti), followed by about 15 min. reaction with H₂S in a chamber at room temperature to form Ag₂S.

### EXAMPLE 12

Ti/Cu₂₋ₓS/BN/Al (or Ti), similar to Example 8, with an about 50-300 Å thick layer of CVD-deposited BN (100 Å presently preferred) substituted for p-SiO₂ as the active layer.

### EXAMPLE 13

Ti/Cu₂₋ₓS/C₃N/Al (or Ti), similar to Example 8, with an about 50-300 Å thick layer of CVD-deposited, amorphous C₃N (100 Å presently preferred) substituted for p-SiO₂ as the active layer.

### EXAMPLE 14

Ti/Cu₂₋ₓS/BaTiO₃/Al (or Ti), similar to Example 8, with an about 50-300 Å thick layer of CVD-deposited, ferroelectric BaTiO₃ substituted for p-SiO₂ as the active layer.

### EXAMPLE 15

Ti/Cu₂₋ₓS/polyester/Al (or Ti), similar to Example 8, with an about 50-300 Å thick layer of spin-coated polystyrene substituted for p-SiO₂ as the active layer.

### EXAMPLE 16

Ti/CuWO₃/p-Si/Al (or Ti), similar to Example 6, except that CuWO₃ is substituted for LiₓTiS₂ as the passive layer. The CuWO₃ passive layer may be formed by first depositing (e.g., vapor depositing) an about 100-300 Å thick layer (150 Å presently preferred) of tungsten (W) on the surface of the lower (Ti) electrode, and reacting the W layer with O₂ gas in a chamber for about 10 min. to form a layer of WO₃. A layer of CuI is then spin-coated onto the layer of WO₃ and the combination reacted at about 150° C. to form CuₓWO₃.

### EXAMPLE 17

Ti/Cu—CuI/p-Si/Al (or Ti), similar to Example 6, except that Cu—CuI is substituted for LiₓTiS₂ as the passive layer. The Cu—CuI passive layer can be formed by first depositing (e.g., vapor depositing) an about 100-300 Å thick layer (150 Å presently preferred) of copper (Cu) on the surface of the lower (Ti) electrode, followed by spin-coating a layer of CuI on the Cu layer.

### EXAMPLE 18

Cu/Cu₂₋ₓS/p-SiO₂/Al (or Ti), similar to Example 8, except that the first electrode is made of Cu rather than Ti.

### EXAMPLE 19

Ag/Ag₂S/p-SiO₂/Al (or Ti), similar to Example 11, except that the first electrode is made of Ag rather than Ti.

Although the invention has been shown and described with respect to certain illustrated aspects, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure, which performs the function in the herein illustrated exemplary aspects of the invention. In this regard, it will also be recognized that the invention includes a system as well as a computer-readable medium having computer-executable instructions for performing the acts and/or events of the various methods of the invention. Furthermore, to the extent that the terms “includes”, “including”, “has”, “having”, and variants thereof are used in either the detailed description or the claims, these terms are intended to be inclusive in a manner similar to the term “comprising.”

What is claimed is:

1. A memory cell comprising:
an active layer with a state changeable based on a migration of electrons or holes therefrom when subject to an external electric field or light radiation, the state indicative of information content;
a passive layer that facilitates supply of charges to the active layer, the passive layer and the active layer exchange electrons or holes, and
a diode component operatively connected to at least one of the passive and active layers to enable a regulation of electric current associated with a programming of the memory cell.

2. The memory cell of claim 1, wherein the active layer comprises material selected from at least one of: organic material, non-organic material, semiconducting material, and inclusion compounds.

3. The memory device of claim 2, wherein the active layer comprises molecular units with redox-active metals.

4. The memory device of claim 3, wherein the redox active metals comprise at least one of: metallocenes complex and polypyridine metal complex.

5. The memory device of claim 2, wherein the active layer comprises at least one of: polyaniline, polythiophene, polypyrrole, polysilane, polystyrene, polyfuran, polyindole, polyazulene, polyphenylene, polypyridine, polybipyridine, polyphthalocyanine, polysexithiofene, poly(siliconoxohemiporphyrazine), poly(germaniumoxohemiporphyrazine), and poly(ethylenedioxythiophene).

6. The memory device of claim 1, wherein the active layer comprises at least one of: hydrocarbons; organic molecules with donor and acceptor properties, metallo-organic complexes; porphyrin, phthalocyanine, and hexadecafluoro phthalocyanine.

7. The memory device of claim 2, wherein the organic material include organic molecules with donor acceptor properties comprises at least one of: N-Ethylcarbazole, tetrathiotetracene, tetrathiofulvalene, tetracyanoquinodimethane, tetracyanoethylene, cloranol, and dinitro-n phenyl.

8. The memory device of claim 6, wherein the metallo-organic complexes are selected from the group of bisdiphenylglyoxime, bisorthophenylenediimine, and tetraaza-tetramethylannulene.

9. The memory device of claim 1, wherein the active layer comprises organic material selected from the group comprising of polyacetylene, polyphenylacetylene, polydiphenylacetylene, polyaniline, poly(p-phenylene vinylene), polythiophene, polyporphyrins, porphyrinic macrocycles, thiol derivatized polyporphyrins, polymetallocenes, polyferrocenes, polyphthalocyanines, polyvinylenes, and polystiroles.

10. The memory device of claim 1, wherein the active layer comprises material selected from the group comprising of electric dipole elements, polymer ferroelectrics clusters, non-organic ferro-electrics, salts, alkalis, acids, and water molecules.

11. The memory device of claim 1, wherein the diode component comprises at least one of a polymeric metallic phthalocyanine (MPc) and a metal hexadecaflouoro phthalocyanine (F16 MPc), wherein the metal (M) is selected from the group of: Cu, Co, Ni, Fe, and T

12. The memory device of claim 1, wherein the diode component comprises at least one aromatic amine.

13. A system that programs a memory cell array comprising:
a plurality of memory cells that are part of an array to be programmed, each memory cell comprising:
an active layer with a state changeable based on a migration of electrons or holes therefrom when subject to an external electric field or light radiation, the state indicative of information content;
a passive layer that facilitates supply of charges to the active layer,
a diode component operatively connected to at least one of the active and passive layers; and
a control component that regulates an external stimulus for the memory cell array, to affect a property associated with memory cells.

14. The system of claim 13, wherein the control component comprises an artificial intelligence unit.

15. The system of claim 13, wherein the control component comprises a comparator that compares measured values with reference values to program the memory cell.

16. A method of fabricating a memory device that operates based upon electron-hole movement through a passive layer and an active layer, comprising:
forming a first electrode on a substrate;
forming the passive layer on the first electrode;
forming the active layer on the passive layer;
forming a diode component operative with at least one of the active layer and the passive layer; and
forming a second electrode on the active layer.

17. The method of claim 16 further comprising forming the active layer via a chemical vapor deposition process.

18. The method of claim 17 further comprising forming the active layer via a gas phase reaction process.

19. The method of claim 16 further comprising forming the active layer formed via a spin coating process or a liquid phase reaction process.

20. The method of claim 16, further comprising applying a voltage to the active layer, to set an impedance state of the memory device, the impedance state representing information content.

21. The method of claim 16, comparing a current flowing through the cell with a predetermined value.

22. A system that programs an array of memory cells comprising:
means for forming a diodic junction operative with passive or active layers of a memory cell that is part of the memory cell array; and
means for changing an impedance state of the memory cell.
